(19) United States
(12) Patent Application Publication
(10) Pub. No.: US 2026/0001998 A1
(43) Pub. Date: Jan. 1, 2026

(54) UV CURABLE RESIN-LINEAR POLYSILOXANE HOT-MELT COMPOSITION

(71) Applicants: Dow Silicones Corporation, Midland, MI (US); Dow Global Technologies LLC, Midland, MI (US)

(72) Inventors: Jongwook Choi, Midland, MI (US); Steven Swier, Midland, MI (US); Yuki Yokouchi, Ichihara (JP)

(21) Appl. No.: 19/108,324

(22) PCT Filed: Sep. 7, 2023
(86) PCT No.: PCT/US2023/032133

§ 371 Date: Mar. 3, 2025

Related U.S. Application Data
(60) Provisional application No. 63/408,499, filed on Sep. 21, 2022.

(51) Int. Cl. C08G 77/18; C08G 77/16; C08J 3/28; H10H 20/854

(52) U.S. Cl. CPC C08G 77/18; C08G 77/16; C08J 3/28; H10H 20/854

(57) ABSTRACT

A hot-melt composition contains: (a) a T^{Ar}-D based resin-linear block copolymer where TAr siloxane unit blocks are linked to D-type siloxane unit blocks with a linkage that in at least some occurrences include an alkenyl group provided that the concentration of such alkenyl groups is in a range of 0.5 to 3.0 mol-percent relative to total moles of silicon atoms in the resin-linear block copolymer; (b) a crosslinker containing an average of at least two (meth)acryloxy groups per molecule; (c) a radical photo-initiator; and optionally (d) an ultraviolet stabilizer; and optionally (c) an adhesion promoter.

### FIELD OF THE INVENTION

The present invention relates to an ultraviolet light curable polysiloxane hot-melt composition, a process for curing such a composition and an article comprising such a composition.

### INTRODUCTION

The mini and micro light emitting diode (LED) market is rapidly growing due in part to use in displays and automotive applications. Mini LED arrays are useful as backlighting panels for standard liquid crystalline displays and improve brightness, contrast and black levels. Micro LEDs refer to tiny LEDs that are used directly as the pixels in a display, specifically combining red, green and blue LED dots. Both technologies require an encapsulant to both protect the fragile LEDs and improve light extraction by replacing air with a silicone interlayer.

Encapsulating compositions have historically been applied to LED components by a liquid injection process. More recently, hot-melt systems have been found to be more desirable for their advantages over liquid injection systems. Such advantages include facile coverage of large areas, process simplicity and re-workability.

One form of encapsulant technology uses silicone encapsulating materials that are cured by hydrosilylation after applying to LED components. Hydrosilylation typically requires elevated temperature, typically exceeding 60 degrees Celsius (° C.) and/or curing times of an hour or more. Unfortunately, some display designs incorporate temperature sensitive materials that cannot be exposed to high temperature without compromising their function. Therefore, in order to protect temperature sensitive materials and increase manufacturing efficiency to meet the increasing need for mini and micro LED devices, it is desirable to identify a hot-melt encapsulating technology that does not require the temperature or time of hydrosilylation curing systems.

WO2017068762 discloses a hot-melt ultraviolet (UV)-curable system that cures using thiol-ene chemistry. While this system can cure at lower temperatures than hydrosilylation curing systems, they use thiol-based reactants which can produce undesirable odors and can result in yellowing.

It would advance the art of LED encapsulants to identify a hot-melt encapsulant composition that cures at temperatures lower than 60° C. and/or has cure times of an hour or less, or even 30 minutes or less and that also does not utilize thiol-based reactants.

### BRIEF SUMMARY OF THE INVENTION

The present invention provides a hot-melt encapsulant composition that cures at temperatures lower than 60° C. and/or has cure times of an hour or less, or even 30 minutes or less and that also does not utilize thiol-based reactants.

The present invention results from discovering a resin-linear technology that can undergo acrylate-ene UV curing, and can be a suitable hot-melt encapsulant composition without requiring unbound nano-phase particulates of MQ resin. The present invention utilizes a T^{Ar}-D based resin-linear block copolymer that has alkenyl functionality in combination with a crosslinker that has multiple (meth)acryloxy groups per molecule to provide a hot-melt composition that can undergo UV acrylate-ene curing at temperatures below 60° C., even at 40° C. or lower, 30° C. or lower, even 25° C. or lower in just minutes, even in less than a minute, without requiring any thiol component.

In a first aspect, the present invention is a hot-melt composition comprising: (a) 80 to 99 mass-parts of at least one a T^{Ar}-D based resin-linear block copolymer comprising T^{Ar}-type siloxane unit blocks and D-type siloxane unit blocks, where: (i) T^{Ar}-type siloxane blocks are joined to D-type siloxane unit blocks with linkages selected from those having structure (I):

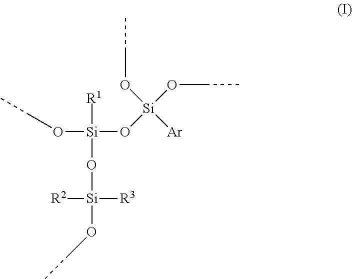

wherein Ar is C₆-C₂₀ aryl; R¹ is selected from C₁-C₂₀ alkyl and C₂-C₂₀ alkenyl groups provided that that the average concentration of alkenyl R¹ groups for the a T^{Ar}-D based resin-linear block copolymer is in a range of 0.5 to 3.0 mole-percent relative to total moles of silicon atoms; and R², and R³ independently are C₁-C₂₀ hydrocarbyl, each dashed line corresponds to a valence bond to a silicon, hydrogen or hydrocarbyl group; and wherein: (ii) the mole ratio of TAr-type siloxane unit blocks to D-type siloxane unit blocks is at least 2; (iii) the resin-linear block copolymer contains 8 to 35 mole-percent Si—OR′ bonds relative to moles of silicone atoms where R′ is H or an a C₁-C₈ hydrocarbyl; (iv) each D-type siloxane unit block contains on average 20 to 200 D-type siloxane units; and (v) each T^{Ar}-type siloxane unit block has a weight-average molecular weight in a range of 500 to 10,000 grams per mole; (b) 0.5 to 20 mass-parts of a crosslinker containing an average of at least two (meth)acryloxy groups per molecule; (c) 0.1 to 10 mass-parts of radical photo-initiator; (d) zero to 2.0 mass-parts of an ultraviolet stabilizer; and (e) zero to 2.0 mass-parts of an adhesion promoter.

In a second aspect, the present invention is a process comprising the steps of heating the hot-melt composition of the first aspect to soften the hot-melt composition and then coating the softened hot-melt composition over at least a portion of a substrate to form a coating of the hot-melt composition over at least a portion of a surface of the substrate

In a third aspect, the present invention is an article comprising the hot-melt composition of the first aspect coating at least a portion of a surface of a substrate.

The composition of the present invention is useful as a LED encapsulant.

### DETAILED DESCRIPTION OF THE INVENTION

Test methods refer to the most recent test method as of the priority date of this document when a date is not indicated with the test method number. References to test methods contain both a reference to the testing society and the test method number. The following test method abbreviations and identifiers apply herein: ASTM refers to American Society for Testing and Materials; EN refers to European Norm; DIN refers to Deutsches Institut für Normung; JIS refers to Japanese Industrial Standards, and ISO refers to International Organization for Standards.

Products identified by their tradename refer to the compositions available under those tradenames on the priority date of this document.

“Multiple” means two or more. “And/or” means “and, or as an alternative”. All ranges include endpoints unless otherwise indicated. Identification of materials by trademark or tradename refers to materials having the composition as sold under that trademark or tradename at the priority date of this document.

“Mass-part” refers to the mass of a component in the composition as measured in the same unit of measure as the mass-parts for the other components in order to provide an indication of the mass of each component relative to the mass of the other components in the composition. For example, a composition comprising 5 grams of component A and 10 grams of component B would have one mass part component A and 2 mass parts component B or, alternatively, 5 mass parts of component A and 10 mass parts of component B. Herein, mass-parts are in reference to the concentration of components in the hot-melt composition are relative to the mass-parts of the other components in the hot-melt composition-meaning all the mass-parts are based on the same unit of mass for the components of the hot-melt composition.

The general terms “C_{x-y}”, “Cₓ-C_{y}”, “Cₓ to C_{y}”, and “Cₓ-C_{y}” are interchangeable in the context of chemical structures and refers to having from x to y carbon atoms in the chemical structure.

Determine number-average molecular weight (Mn), weight-average molecular weight (Mw), polydispersity index (PDI) and free resin % values for materials by gel permeation chromatography (GPC) using the following method: Sample preparation: The samples were prepared in toluene eluent at a concentration of 20 mg/mL polymer. The solution was shaken on a flat-bed shaker at ambient temperature for about 2 hours. The solution was filtered through a 0.45 um PTFE syringe filter prior to injection. GPC was performed on a Viscotek GPC Max pump and autosampler. The flow rate was set at 1 mL/min, and the injection volume was set at 100 microliters for standards and 200 uL for research samples. Each sample was run in duplicate injections. Separation was carried out on 2 Agilent Plgel Mixed-B columns held at 35° C. The detector was a Viscotek TDA 305 triple detector array held at 35° C. Triple detector includes RI, UV, LALS, RALS, and DP. Software and data process: Malvern OMNISEC 5.02 was used for data collection and Malvern OMNISEC 5.12 was used for data reduction. A total of 17 PS linear narrow molecular weight standards from Agilent having Mp values from 4,000 to 0.58 kg/mol were used for conventional molecular weight calibration. A 3^{rd} order polynomial was used for calibration curve fitting. Thus, all molecular weight averages, distributions and references to molecular weight provided in this report are polystyrene (PS) equivalent values and only RI was used for molecular weight calculation.

In one aspect, the present invention is a hot-melt composition. A “hot-melt” composition is characterized as having a softening point of 50 degrees Celsius (° C.) or higher while at the same time typically 150° C. or lower. The hot-melt composition of the present invention desirably has a softening point of 50° C. or higher, preferably 60° C. or higher, 70° C. or higher, 80° C. or higher, 90° C. or higher, and can be 100° C. or higher, while at the same time is desirably 150° C. or lower, preferably 125° C. or lower, even 100° C. or lower. Determine softening point for a composition by the ring-and-ball method of JIS K6863-1994. Softening of a hot-melt composition is reversible, meaning that the hot-melt composition can repeatedly be heated above and cooled below its softening point while maintaining hot-melt behavior.

Desirably, the hot-melt composition of the present invention has a storage modulus at 25° C. of greater than 0.01 MegaPascal (MPa) and a tan δ at 25° C. of less than 2.0 or preferably 1.5 or less, which means the hot-melt composition is non-flowable at 25° C. It is further desirable for the hot-melt composition of the present invention to have one or any combination of more than one of the following additional characteristics that make it particularly suitable as an LED encapsulant: (i) a ratio of viscosity at 25° C. divided by the viscosity at 100° C. with viscosity measured in kiloPascals that is 20 or more, preferably 100 or more while at the same time is typically 10,000 or less, and can be 5000 or less, 4000 or less, even 3800 or less; (ii) a storage modulus at 25° C. that is preferably greater than 0.1 MPa while at the same time is typically 100 MPa or less, or even 50 MPa or less, 25 MPa or less, 10 MPa or less, or even 8.5 MPa or less, or 8 MPa or less; and (iii) a Tan δ value at 25° C. that is preferably 2.0 or less while at the same time is typically 0.01 or more and can be 0.05 or more, 0.10 or more, even 0.12 or more. Determine composition viscosity, storage modulus and Tan δ values for a composition by rotational rheometry using and ARES-G2 device from TA instruments with 25 millimeter parallel plates and one millimeter sample thicknesses. Equilibrate the sample in the testing device at 20° C. for 5 minutes and then ramp the temperature up to 120° C. at a rate of 3° C./minute collecting data every 9 seconds.

The hot-melt composition comprises: (a) a T^{Ar}-D based resin-linear block copolymer; (b) a crosslinker; (c) a radical photo-initiator; optionally (d) an ultraviolet stabilizer; and optionally (e) an adhesion promoter. The hot-melt composition can be and desirably is free of mercapto-functional siloxane. The hot-melt composition is even more desirably free of any mercapto-functional components. The hot-melt can additionally, or alternatively also be free of unbound Q-based resin particles. “Unbound” refers to being free of covalent bonds to either the T^{Ar}-D based resin-linear block copolymer or crosslinker. “Q-based resin particles” refers to particles of polysiloxane consisting of greater than 40 mol %, often greater than 50 mol % SiO₄₂ siloxane units relative to all siloxane units in the polysiloxane molecule, where O_{4/2} refers to four oxygen atoms each bound to the silicon atom and shared with another silicon atom to form a siloxane bond.

A “resin-linear block copolymer” refers to a block copolymer comprising one or more than one block of linear polymer bound to one or more than one block of resinous polymer. A “block” refers to a repeating section of multiple units of the same basic type. The T^{Ar}-D based resin-linear block copolymer comprises T^{Ar}-type siloxane unit blocks, which are blocks of resinous polymer, and D-type siloxane unit blocks, which are blocks or linear polymer.

T^{Ar}-type siloxane units have chemical formula:

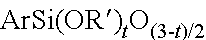

where:
Ar refers to an aryl group having 6 or more, and can have 7 or more, 8 or more, 9 or more, 10 or more, 12 or more, 14 or more, 16 or more, even 18 or more while at the same time typically has 20 or fewer, and can have 18 or fewer, 16 or fewer, 14 or fewer, 12 or fewer, 10 or fewer, 8 or fewer carbon atoms, while preferably the aryl group is a phenyl group;
R′ in each occurrence is independently selected from hydrogen and hydrocarbyl groups, where they hydrocarbyl groups preferably have one or more, and can have 2 or more, 3 or more, 4 or more, 5 or more, 6 or more, even 7 or more while at the same time typically have 8 or fewer and can have 7 or fewer, 6 or fewer, 5 or fewer, 4 or fewer, 3 or fewer, even 2 or fewer carbon atoms;
Subscript t is the number of (OR′) groups attached to the silicon atom and typically has a value in a range of zero to 2; and
O_{(3-t)/2} refers to (3-t) oxygen atoms bound to the silicon atom and that are shared with another silicon atom to form a siloxane bond.

A block of T^{Ar}-type siloxane units comprises multiple T^{Ar}-type siloxane units bound together through shared siloxane bonds.

D-type siloxane units have the general chemical formula: R₂SiO_{2/2}; where O_{2/2} refers to two oxygen atoms bound to the silicon atom and shared with another silicon atom to form a siloxane bond; and each R is independently selected from hydrocarbyl groups having one or more, and that can have 2 or more, 3 or more, 4 or more, 5 or more, 6 or more, even 7 or more, 8 or more, 10 or more, 12 or more, 14 or more, 16 or more, even 18 or more, while at the same time typically have 20 or fewer, 18 or fewer, 16 or fewer, 14 or fewer, 12 or fewer, 10 or fewer, 8 or fewer and can have 7 or fewer, 6 or fewer, 5 or fewer, 4 or fewer, 3 or fewer, even 2 or fewer carbon atoms. Typically, each R group is methyl. A block of D-type siloxane units comprises multiple D-type siloxane units bound together through shared siloxane bonds.

The T^{Ar}-D based resin-linear block copolymer is further characterized by the following characteristics:
(i) T^{Ar}-type siloxane blocks are joined to D-type siloxane unit blocks with linkages selected from those having structure (I):

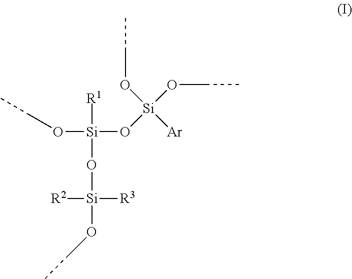

wherein: Ar is as described hereinabove; R¹ is selected from C₁-C₂₀ alkyl and C₂-C₂₀ alkenyl group (preferably vinyl groups) provided that that the average concentration of R¹ groups alkenyl groups for the a T^{Ar}-D based resin-linear block copolymer is in a range of 0.5 to 3.0 mole-percent (mol %) and can be 0.5 mol % or more, 0.75 mol % or more, 1.0 mol % or more, 1.5 mol % or more, 2.0 mol % or more, even 2.5 mol % or more while at the same time is 3.0 mol % or less, and can be 2.5 mol % or less, 2.0 mol % or less, 1.5 mol % or less, even 1.0 mol % or less relative to total moles of silicon atoms; and R², and R³ independently are selected from R groups as described hereinabove and are preferably selected from methyl and ethyl groups; and each dashed line corresponds to a valence bond to a silicon, hydrogen or hydrocarbyl group
(ii) the mole ratio of T^{Ar}-type siloxane unit blocks to D-type siloxane unit blocks is 2 or more and preferably each D-type siloxane unit is capped on either end with a T^{Ar}-type siloxane unit block;
(iii) the T^{Ar}-D based resin-linear block copolymer has sufficient OR′ groups present to provide 8 or more, and possibly 9 or more, 10 or more, 11 or more, 12 or more, 14 or more 16 or more, 18 or more, 20 or more, 22 or more, 24 or more, 26 or more, even 28 or more while at the same time 35 or less, and possibly 30 or less, 25 or less, 20 or less, 15 or less, even 10 or less mole-percent (mol %) Si—OR′ bonds relative to total moles of silicone atoms in the T^{Ar}-D based resin-linear block copolymer; and
(iv) each D-type siloxane unit block contains on average 10 to 200 D-type siloxane units and can contain 10 or more, 20 or more, 30 or more, 40 or more, 50 or more, 60 or more, 70 or more, 80 or more, 90 or more, 100 or more, 120 or more, 140 or more, 160 or more, even 180 or more while at the same time typically contain 200 or fewer, 180 or fewer, 160 or fewer, 140 or fewer, 120 or fewer, 100 or fewer, 90 or fewer, 80 or fewer, 70 or fewer, 60 or fewer, 50 or fewer, 40 or fewer, 30 or fewer, even 20 or fewer D-type siloxane units on average; and
(v) each T^{Ar}-type siloxane unit block has a weight-average molecular weight (Mw) in a range of 500 to 10,000 grams per mole, and can have a Mw of 500 or more, 750 or more, 1000 or more, 2500 or more, 5000 or more, even 7500 or more while at the same time is typically 10,000 or less, 7500 or less, 5000 or less, 2500 or less, and can be 1000 or less, even 750 or less.

Determine the average number of D-type siloxane units in the T^{Ar}-D based resin-linear block copolymer by ²⁹Si NMR spectroscopy]. Determine average Mw for a T^{Ar}-type siloxane unit blocks in a T^{Ar}-D based resin-linear block copolymer by gel permeation chromatography (GPC) using the procedure stated herein above.

The T^{Ar}-D based resin-linear block copolymer can be free of (meth)acryloxy groups. In fact, the entire composition can be free of (meth)acyloxy functional polysiloxanes.

The hot-melt composition comprises 80 mass-parts or more, and can comprise 85 mass-parts or more, 90 mass parts or more, 95 mass-parts or more, even 97 mass-parts or more while at the same time typically comprises 99 mass-parts or less and can comprise 98 mass-parts or less, 95 mass-parts or less, 90 mass-parts or less, even 85 mass-parts or less of at least one T^{Ar}-D based resin-linear block copolymer.

The T^{Ar}-D based resin-linear block copolymer can be free of alkenyl-functional R″₃SiO_{1/2} siloxane units where R″ is a hydrocarbyl and O_{1/2} refers to an oxygen bound to the silicon atom and shared with another silicon atom in a siloxane bond.

The crosslinker is a molecule that contains an average of two or more (meth)acryloxy groups per molecule and can contain 3 or more, even 4 or more while at the same time typically contains 8 or fewer, 7 or fewer, 6 or fewer, 5 or fewer, 4 or fewer, even 3 or fewer (meth)acryloxy groups per molecule.

In order to avoid loss of composition components during heating (that is, to achieve stable curability) it is desirable for the crosslinker and/or radical photo-initiator to have a boiling point at 101 kiloPascals pressure that is above 100° C., preferably that is 150° C. or higher, and more preferably 200° C. or higher while at the same time is generally 400° C. or lower, and can be 350° C. or lower, 300° C. or lower, 250° C. or lower, even 200° C. or lower.

The crosslinker can be one or more than one compound selected from compounds having average chemical structure (III) and (IV):

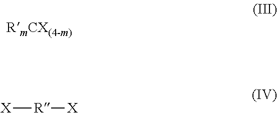

where:
   each R′ is independently in each occurrence selected from alkyl groups having from one to 20 carbon atoms, and can have one or more, 2 or more, 3 or more, 4 or more, 5 or more, 6 or more, 7 or more, 8 or more, 10 or more, 12 or more, 14 or more, 16 or more, even 18 or more while at the same time typically have 20 or fewer, 18 or fewer, 16 or fewer, 14 or fewer, 12 or fewer, 10 or fewer, 8 or fewer, 6 or fewer, 4 or fewer, even 2 or fewer carbon atoms;
   each X is independently selected from —CH₂OC(O)CH═CH₂ and —CH₂OC(O)C(CH₃)═CH₂ groups, and
   R″ is an alkylene group having from one to 20 carbon atoms, and can have one or more, 2 or more, 3 or more, 4 or more, 5 or more, 6 or more, 7 or more, 8 or more, 9 or more, 10 or more, 11 or more, 12 or more, 14 or more, 16 or more, even 18 or more while at the same time 20 or fewer, 18 or fewer, 16 or fewer, 14 or fewer, 12 or fewer, 10 or fewer, 8 or fewer, 6 or fewer, 4 or fewer, even 2 or fewer carbon atoms.

Examples of suitable crosslinkers include trimethylpropane triacrylate, pentaerythritol tetraacrylate, and 1,12-dodecanediol dimethacrylate.

The concentration of crosslinker in the hot-melt composition is typically in a range of 0.5 to 20 mass-parts, and can be present at a concentration of 0.5 or more, 1.0 or more, 2.0 or more, 4.0 or more, 6.0 or more, 8.0 or more, 10.0 or more, 12.0 or more, 14.0 or more, 16.0 or more, even 18.0 or more while at the same time is typically 20.0 or less, 18.0 or less, 16.0 or less, 14.0 or less, 12.0 or less, 10.0 or less, 8.0 or less, 5.0 or less, 4.0 or less, 3.0 or less, 2.0 or less, even 1.0 or less mass-parts.

The hot-melt composition comprises a radical photo-initiator at a concentration of 0.1 mass-parts or more, 0.5 mass-parts or more, 1.0 mass-parts or more, 2.0 mass-parts or more, 3.0 mass-parts or more, 4.0 mass-parts or more, 5.0 mass-parts or more, 6.0 mass-parts or more, 7.0 mass-parts or more, 8.0 mass-parts or more, even 9.0 mass-parts or more while at the same time 10 mass-parts or less, 9.0 mass-parts or less, 8.0 mass-parts or less, 7.0 mass-parts or less, 6.0 mass-parts or less, 5.0 mass-parts or less, 4.0 mass-parts or less, 3.0 mass-parts or less, 2.0 mass-parts or less, even 1.0 mass-parts or less.

The radical photo-initiator can be, for example, any one or combination of more than one component selected from a group consisting of benzophenone and benzophenone derivatives, acetophenone and acetophenone derivatives, benzoin and its alkyl esters, phosphine oxide derivatives, xanthone derivatives, oxime ester derivatives, and camphor quinone. Suitable commercially available photoinitiator include any one or any combination of more than one selected from 2,6-bis(4-azido benzylidene)cyclohexanone; 2,6-bis(4-azido benzylidene)-4-methylcyclohexanone; 1-hydroxyl-cyclohexyl-phenyl-ketone (available under the name OMNIRAD™ 184); 2-methyl-1 [4-(methylthio)phenyl]-2-morpholinopropane-1-one (available under the name OMNIRAD 907); 2-hydroxy-2methyl-1-phenyl-propane-1-one (available under the name OMNIRAD 1173); 2-hydroxy-1-[4-(2-hydroxyethoxy)phenyl]-2-methyl-1-propanone (available under the name OMNIRAD 2959); methylbenzoylformate (available under the name OMNIRAD MBF); alpha, alpha-dimethoxy-alpha penylacetophenone (available under the name OMNIRAD 651); 2-benzyl-2-(dimethylamino)-1-[4-(4-morpholinyl)phenyl]-1-butanone (available under the name OMNIRAD 369);diphenyl (2,4,6-trimethylbenzoyl) phosphine oxide (available under the name OMNIRAD TPO); ethyl (2,4,6-trimethylbenzoyl)phenyl phosphinate (available under the name OMNIRAD TPO-L); oxime ester compounds (available as products N-1919, NCI-831, NCI-930, NCI-730 and NCI-100 from Adeka Corporation), 12-hioxanthene-9-one; 10-methylpehenothiazine; isopropyl-9H-thioxanthen-9-one; 2,4-diethyl-9H-thoxanthen-9-one; 2-chlorothioxanthen-9-one; and 1-chloro-4-propoxy-9H-thioxanthen-9-one. OMNIRAD is a trademark of IGM Group B.V. One particularly desirably radical photo-initiator is 2,4,6-trimethylbenzoyl-phenylphosphinate.

Optionally, the hot-melt composition can comprise an ultraviolet stabilizer. Ultraviolet stabilizers are radical scavengers and they can extend the storage stability of the hot-melt composition by inhibiting curing until intentionally exposing the hot-melt composition to UV light. Ultraviolet stabilizers include phenolic compounds such as any one or any combination of more than one of 4-methoxyphenol (MEHQ, methyl ether of hydroquinone), hydroquinone, 2-methylhydroquinone, 2-t-butylhydroquinone, t-butyl catechol, butylated hydroxy toluene, and butylated hydroxy anisole. Other types of ultraviolet stabilizers include phenothiazine and anaerobic inhibitors such as NPAL type inhibitors (tris-(N-nitroso-N-phenylhydroxylamine) aluminum salt) available from Albemarle Corporation.

The concentration of ultraviolet stabilizer is typically zero mass-parts or more, and can be 0.1 mass-parts or more, 0.5 mass-parts or more, 1.0 mass-parts or more, even 1.5 mass-parts or more while at the same time are typically 2.0 mass-parts or less, 1.5 mass-parts or less, 1.0 mass-parts or less, even 0.5 mass-parts or less.

Optionally, the hot-melt composition can comprise an adhesion promoter. Suitable adhesion promoters include organosilicon compounds having at least one silicon-bonded alkoxy group in a molecule. This alkoxy group is exemplified by a methoxy group, an ethoxy group, a propoxy group, a butoxy group, or a methoxyethoxy group, among which a methoxy group is particularly preferred. Moreover, silicon-bonded groups other than alkoxy groups in the organosilicon compound are exemplified by halogen-substituted or unsubstituted monovalent hydrocarbon groups such as alkyl groups, alkenyl groups, aryl groups, aralkyl groups, halogenated alkyl groups, halogenated aryl groups, and halogenated aralkyl group; glycidoxylalkyl groups such a 3-glyidoxypropyl group, and a 4-glycidoxybutyl group; epoxycyclohexylalkyl groups such as a 2-(3.4-epoxycyclo hexyl)ethyl group and a 3-(3.4-epoxycyclohexyl) propyl group; epoxyalkyl groups such as a 3.4-epoxybutyl group, and a 7.8-epoxyoctyl group; acrylic group containing monovalent organic groups such as a 3-meth acryloxypropyl group; and a hydrogen atom. The adhesion promoter preferably contains a group that can react with the alkenyl groups or silicon-bonded hydrogen atoms. Specifically, the adhesion promoter preferably contains a silicon-bonded hydrogen atom or an alkenyl group. Moreover, due to the ability to impart good adhesion to various types of substrates, the adhesion promoter preferably has at least one epoxy group-containing monovalent organic group in a molecule. This type of adhesion promoter is exemplified by organosilane compounds, organosiloxane oligomers, and alkyl silicates. The molecular structure of the organosiloxane oligomer or alkyl silicate is exemplified by linear, partially branched linear, branched chain, cyclic, and net-shaped structures. Linear, branched chain, and net shaped structures are particularly preferred. The adhesion promoter is exemplified by silane compounds such as 3-glycidoxy propyltrimethoxysilane. 2-(3.4-epoxycyclohexyl)ethyl trimethoxysilane, and 3-methacryloxypropyltrimethoxysilane; siloxane compounds having at least one each of silicon-bonded alkenyl groups or silicon-bonded hydrogen atoms and silicon-bonded alkoxy groups in a molecule: mixtures of a silane compound or siloxane compound having at least one silicon-bonded alkoxy group and a siloxane compound having at least one silicon-bonded hydroxyl group and at least one silicon-bonded alkenyl group in a molecule; and methyl polysilicate, ethyl polysilicate, and epoxy group-containing ethyl polysilicate. The adhesion promoter is preferably a low-viscosity liquid, and its viscosity is not particularly limited but is preferably from 1 to 500 milliPascal (mPa) at 25° C.

The concentration of adhesion promoter is typically zero mass-parts or more, and can be 0.1 mass-parts or more, 0.5 mass-parts or more, 1.0 mass-parts or more, even 1.5 mass-parts or more while at the same time are typically 2.0 mass-parts or less, 1.5 mass-parts or less, 1.0 mass-parts or less, even 0.5 mass-parts or less.

Notably, the hot-melt composition of the present invention can be free of hydrosilylation catalyst such as platinum catalysts. As such, the hot-melt composition can be free of platinum, which can be desirable to avoid yellowing of the composition and to keep costs lower than systems that require platinum catalysts.

In another aspect, the present invention is a process for using the hot-melt composition of the present invention as a curable coating on a substrate. The process comprises the steps of heating the hot-melt composition of the present invention to soften the hot-melt composition and then coating the softened hot-melt composition over at least a portion of a substrate to form a coating of the hot-melt composition over at least a portion of a surface of the substrate. The process can further comprise exposing the coating of the hot-melt composition to ultraviolet light to cause crosslinking of the composition coating. Crosslinking occurs as the (meth)acryloxy groups of the crosslinker react with the alkenyl groups of the T^{Ar}-D based resin-linear block copolymer.

In a particularly desirable application the hot-melt composition of the present invention is an encapsulant for light emitting diodes. In such an application, the process is as described and the substrate over which the hot-melt composition is coated comprises light emitting diodes. The coating covers the light emitting diodes thereby encapsulating them and then the coating is cured by exposure to UV light.

In yet another aspect, the present invention is an article comprising the hot-melt composition of the present invention coating at least a portion of a surface of a substrate. Desirably, the substrate, and most desirably the portion of the substrate coated by the hot-melt composition, comprises light emitting diodes.

### Examples

### Synthesis of Silanol Terminated Polydimethylsiloxane (PDMS)

Prepare the Silanol-Terminated PDMS materials for the following examples by starting with a shorter chain silanol-terminated PDMS and reacting to build to a longer chain silanol terminated-PDMS using a potassium hydroxide (KOH) catalyst solution while purging the reaction with nitrogen to remove water during the reaction. Monitor chain length by monitoring changes in the concentration of OH bands in Fourier Transform Infrared Spectroscopy (FT-IR). Different chain lengths can be made by starting with different chain length silanol-terminated PDMS, using different concentrations of catalyst and by running the reaction for different times. Once the reaction is done, confirm the degree of polymerization (DP) by ²⁹Si NMR. The Silanol-Terminated PDMS materials for the following examples are characterized in Table 1.

TABLE 1

| | | Degree of |
|---|---|---|
| | | Polymerization |
| Sample | General structure | (DP = m) |
| Silanol-Terminated PDMS 1 | H—(OSiMe₂)ₘ—OH | 54 |
| Silanol-Terminated PDMS 2 | | 98 |
| Silanol-Terminated PDMS 3 | | 88 |
| Silanol-Terminated PDMS 4 | | 63 |

Below is the procedure for the longest and shortest Silanol-Terminated PDMS used in the examples. One or ordinary skill should be able to prepare the mid-range Silanol-Terminated-PDMS materials based on those procedures. The procedures use a starting silanol-terminated PDMS having a viscosity in a range of 50 to 120 centiStokes (Commercially available under the name XIAMETER™ PMX-0156 from The Dow Chemical Company. XIAMETER is a trademark of Dow Silicones Corporation. DOWSIL is a trademark of The Dow Chemical Company.)

### Silanol-Terminated PDMS 1: Degree of Polymerization (DP)=54

Add 500.0 g of starting silanol-terminated PDMS into a one-liter 3-neck round bottom flask equipped with a polytetrafluoroethylene stir paddle and a thermocouple, leaving one neck open while purging with nitrogen gas at a flow rate of 1.5 standard cubic feet per hour. Add 0.17 g of 3 wt % potassium hydroxide solution to the flask at 90° C. After 3 hours at 90° C., add 0.53 g of 2.5 wt % aqueous phosphoric acid solution. Cool the solution to 25° C. Purge with nitrogen gas overnight to remove water. Filter through a nylon filter to obtain PDMS 1. ²⁹Si NMR confirms that PDMS 1 has a DP of 54.

### Silanol-Terminated PDMS 2: DP=98

Add 1255.6 g of starting silanol-terminated PDMS into a one-liter 3-neck round bottom flask equipped with a polytetrafluoroethylene stir paddle and a thermocouple, leaving one neck open while purging with nitrogen gas at a flow rate of 1.5 standard cubic feet per hour. Add 0.42 g of 3 wt % potassium hydroxide solution to the flask at 90° C. After 3 and ½ hours at 90° C., add 1.32 g of 2.5 wt % aqueous phosphoric acid solution. Cool the solution to 25° C. Purge with nitrogen gas overnight to remove water. Filter through a nylon filter to obtain PDMS 2. ²⁹Si NMR confirms that PDMS 2 has a DP of 98.

### Synthesis of T^{Ar}-D Based Resin-Linear Block Copolymers RL1-RL6

In addition to PDMS 1-4, Table 2 lists the components used with a Silanol-Terminated PDMS to make RL1-RL6.

TABLE 2

| Material | Description | Source |
|---|---|---|
| Resin | T^{Ph} resin with a weight-average molecular weight | Available under the name |
| | of 2,660 and containing an average of 8.5 mol % | DOWSIL ™ RSN 217 flake |
| | OH. TPh resin is a polymer of PhSi(OH)ₜO_{(3-t)/2} | from The Dow Chemical |
| | siloxane units where Ph refers to a phenyl group. | Company. |
| VTA | Vinyltetracetoxysilane | Gelest |
| Acetoxysilane | A 1:1 mixture of methyltriacetoxysilane and | Available under the name |
| | ethyltriacetoxy silane | XIAMETER ™ OFS-1579 |
| | | from The Dow Chemical |
| | | Company. |
| Toluene | Toluene | Sigma-Aldrich |

DOWSIL is a trademark of The Dow Chemical Company.

### RL1: 45 wt % Resin/55 wt % Silanol-Terminated PDMS 1 and Vinyl Functionalized

Load 90.0 g Resin and 185.5 g toluene into a one-liter (1 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 8.50 g VTA and 5.49 of Acetoxysilane to a mixture of 59.2 g toluene and 110.0 g Silanol-Terminated PDMS 1 in a 500 milliliter round bottom flask. Stir the mixture for one hour. Quickly add the resulting diacetoxy silane terminated PDMS to the flask containing the resin at 106° C. to form a reaction mixture. Reflux for 2 hours. Cool the reaction mixture to 90° C. and add 21.9 g deionized water. Remove water and acetic acid by-product by azeotropic distillation. Add and remove water one more time. Remove 81.0 g of volatiles by distillation to obtain a concentration solution. Repeat three times addition and removal of water. Filter the resulting solution through a 5 micrometer nylon filter. Reduce volatiles to increase solids contents using a rotovap. A translucent solution of RL1 in toluene remains with an active concentration of RL1 that is 79.6 mass % based on solution mass.

RL2:35 wt % Resin/65 wt % Silanol-Terminated PDMS 2 and Vinyl Functionalized Load 70.0 g Resin and 230.0 g toluene into a one-liter (1 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 8.50 g VTA and 0.56 of Acetoxysilane to a mixture of 70.0 g toluene and 130.0 g Silanol-Terminated PDMS 2 in a 500 milliliter round bottom flask. Stir the mixture for one hour. Quickly add the resulting diacetoxy silane terminated PDMS to the flask containing the resin at 106° C. to form a reaction mixture. Reflux for 2 hours. Cool the reaction mixture to 106° C. and add 1.75 g Acetoxysilane. Reflux for one hour. Cool the mixture to 25° C. and add 16.9 g deionized water. Remove water and acetic acid by-product by azeotropic distillation. Add and remove water one more time. Remove volatiles by distillation to obtain a concentration solution. Repeat three times addition and removal of water. Filter the resulting solution through a 5 micrometer nylon filter. Reduce volatiles to increase solids contents using a rotovap. A translucent solution of RL2 in toluene remains with an active concentration of RL2 in toluene of 72.9 mass % based on solution mass.

RL3:45 wt % Resin/55 wt % Silanol-Terminated PDMS 4 and vinyl functionalized

Load 270.0 g Resin and 722.3 g toluene into a 3-liter (3 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 25.50 g VTA and 10.36 g of Acetoxysilane to a mixture of 177.7 g toluene and 330.0 g Silanol-Terminated PDMS 4 in a 500 milliliter round bottom flask. Stir the mixture for one hour. Quickly add the resulting diacetoxy silane terminated PDMS to the flask containing the resin at 106° C. to form a reaction mixture. Reflux for 2 hours. Cool the mixture to 90° C. and add 56.0 g deionized water. Remove water and acetic acid by-product by azeotropic distillation. Add and remove water one more time. Remove 300.0 g of volatiles by distillation to obtain a concentration solution. Repeat three times addition and removal of water. Filter the resulting solution through a 5 micrometer nylon filter. Reduce volatiles to increase solids contents using a rotovap. A translucent solution of RL3 in toluene remains with an active RL3 concentration of 78.7 mass % based on solution mass.

RLA: 45 wt % Resin/55 wt % Silanol-Terminated PDMS 2 and Vinyl Functionalized Load 90.0 g Resin and 230.0 g toluene into a one-liter (1 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 7.71 g VTA to a mixture of 70.0 g toluene and 110.0 g Silanol-Terminated PDMS 2 in a 500 milliliter round bottom flask. Stir the mixture for one hour. Quickly add the resulting diacetoxy silane terminated PDMS to the flask containing the resin at 106° C. to form a reaction mixture. Reflux for 2 hours. Cool the reaction mixture to 106° C. and add 0.79 g VTA and 6.72 g Acetoxysilane. Reflux for one hour. Cool the mixture to 90° C. and add 23.8 g deionized water. Remove water and acetic acid by-product by azeotropic distillation. Add and remove water one more time. Remove volatiles by distillation to obtain a concentration solution. Repeat three times addition and removal of water. Filter the resulting solution through a 5 micrometer nylon filter. Reduce volatiles to increase solids contents using a rotovap. A translucent solution of RL4 in toluene remains with an active RL4 concentration of 71.1 mass % based on solution mass.

### RL5:45 wt % Resin/55 wt % Silanol-Terminated PDMS 3 and Vinyl Functionalized

Load 90.0 g Resin and 240.8 g toluene into a one-liter (1 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 8.50 g VTA to a mixture of 59.2 g toluene and 110.0 g Silanol-Terminated PDMS 3 in a 500 milliliter round bottom flask. Stir the mixture for one hour at 25° C. Quickly add the resulting diacetoxy silane terminated PDMS to the flask containing the resin at 106° C. to form a reaction mixture. Reflux for 2 hours. Cool the reaction mixture to 106° C. and add 7.49 g Acetoxysilane. Reflux for one hour. Cool the mixture to 90° C. and add 25.1 g deionized water. Remove water and acetic acid by-product by azeotropic distillation. Add and remove water one more time. Remove 100 g volatiles by distillation to obtain a concentration solution. Repeat three times addition and removal of water. Filter the resulting solution through a 5 micrometer nylon filter. Reduce volatiles to increase solids contents using a rotovap. A translucent solution of RL5 in toluene remains with an active RL5 concentration of 78.7 mass % based on solution mass.

### RL6:45 wt % Resin/55 wt % Silanol-Terminated PDMS 4 and No Alkenyl Functionalization

Load 90.0 g Resin and 240.8 g toluene into a one-liter (1 L) four-neck round bottom flask equipped with a thermocouple, polytetrafluoroethylene stir paddle, and a Dean Stark apparatus attached to a water-cooled condenser. Add enough additional toluene equal to the volume of the Dean Stark apparatus. Apply an inert gas blanket and reflux for 30 minutes to remove water.

Prepare diacetoxy silane terminated PDMS by adding 11.78 g Acetoxysilane to a mixture of 59.3 g toluene and 110.0 g Silanol-Terminated PDMS 4 in a 500 milliliter round bottom flask. Stir the mixture for one hour. Quickly add the resulting diacetoxy silane terminated PDMS to the flask containing the resin at 106° C. to form a reaction mixture. Reflux for 2 hours. Cool the solution to 25° C. and add 18.7 g deionized water. Remove water and acetic acid by-product by azeotropic distillation. Add and remove water one more time. Remove volatiles by distillation to obtain a concentration solution. Repeat three times addition and removal of water. Filter the resulting solution through a 5 micrometer nylon filter. Reduce volatiles to increase solids contents using a rotovap. A translucent solution of RL6 in toluene remains with an active RL6 concentration of 73.1 mass % relative to solution mass.

Table 3 presents a summary of the characteristics of the T^{Ar}-D based resin-linear block copolymers RL1-RL6.

TABLE 3

| | | | | | | | | Free | # of |
|---|---|---|---|---|---|---|---|---|---|
| | | | | | | | | resin | vinyls |
| | Functional | Resin | Linear | DP of | | | | wt % of | per |
| Sample | group | wt % | wt % | PDMS | Mn | Mw | PDI | solids | chain |
| RL 1 | Vinyl | 45 | 55 | 54 | 19,504 | 97,867 | 5.0 | 22.0% | 3.5 |
| RL 2 | functionalized | 35 | 65 | 98 | 22,187 | 68,413 | 3.1 | 28.0% | 4.0 |
| RL 3 | RL | 45 | 55 | 63 | 17,481 | 49,788 | 2.8 | 31.0% | 3.2 |
| RL 4 | | 45 | 55 | 98 | 24,535 | 78,284 | 3.2 | 35.2% | 4.4 |
| RL 5 | | 45 | 55 | 88 | 22,630 | 70,521 | 3.1 | 30.8% | 4.1 |
| RL 6 | Non alkenyl RL | 45 | 55 | 63 | 18,466 | 49,422 | 2.7 | 34.9% | 0 |

### Sample Compositions

Prepare the following Sample Compositions using RL1-RL6 and Table 4 components.

TABLE 4

| Material | Description | Source |
|---|---|---|
| MP148SP | [ViMe₂SiO_{1/2}]₂[Me₂SiO_{2/2}]₂₁₀[Ph₂SiO_{2/2}]₅₁ where | Prepare according to |
| | Vi refers to a vinyl group, Me refers to a methyl | synthetic procedures in |
| | group, and Ph refers to a phenyl group | U.S. Pat. No. 10,336,913B2 |
| Crosslinker 1 | Trimethylpropane triacrylate (>75% purity) | TCI America |
| Crosslinker 2 | Pentaerythritol tetraacrylate (95%) | Available from eMolecules |
| Crosslinker 3 | 1,12-dodecanediol dimethacrylate | TCI America |
| Crosslinker 4 | Lauryl methacrylate | Aldrich |
| Photo Initiator | Ethyl (2,4,6-trimethylbenzoyl)-phenylphosphinate | Available from Oakwood |
| | | Chemical |

Prepare samples by uniformly mixing the mass-parts designated in Table 5 of each component together in toluene to form a sample. Use for the resin-linear components the solution of the resin-linear component in toluene as prepared, with the amount corresponding to the mass-part of active (that is, mass-part Resin-Linear Block Copolymer) as stated in Table 5. Combine the components in a dental cup and uniformly mix the components together using a dental mixer. Coat the formulation on an ethylene tetrafluoroethylene (ETFE) film and dry at 70° C. for one hour prior to characterization.

Characterize the dried samples to determine whether they meet the requirements for being a “hot-melt” composition, as set forth above by having a softening point in a range of 50-150° C. by JIS K6863-1994, a storage modulus at 25° C. of greater than 0.01 MPa, a Tan δ value at 25° C. that is less than 5.0, and a ratio of viscosity at 25° C. to viscosity at 100° C. that is greater than 20. Characterize the sample also for their “curability”. To be suitably UV curable the samples must pass the following UV-Curability Test. To be suitable for optical encapsulants, such as an LED encapsulant, the composition should cure to a material having a percent-transmittance (% T) to optical light that is greater than 90%. Determine % T using the procedure below. [Ac]/[Vi] is the molar ratio of (meth)acryloxy groups to vinyl groups in the composition. Characterization results for the various samples are summarized in Table 5.

### UV-Curability Test

Coat a sample onto an ethylene tetrafluoroethylene (ETFE) film and allow to dry at 70° C. to form a 200 micrometer thick film of sample. Cover the sample film with another ETFE film so as to sandwich the sample film between ETFE films. Place the sandwiched sample into a UVitron SkyRAY with Raven change and expose to 365 nanometer UV radiation (250 milliWatts) for 16 seconds. Flip the sample and repeat the exposure. The total UV dosage is 8 Joules per square centimeter of UV radiation (4 Joules per square centimeter on each side).

### Gel Percent

Determine Gel Percent (Gel %) by weighing a sample (approximately 1.0 g) of cured hot-melt composition to get a starting sample mass and placing the sample into a 40 milliliter dental cup, add 15.0 g of toluene to the dental cup and shake for one hour, decant off toluene solution leaving behind undissolved cured hot-melt material. Transfer the undissolved cured hot-melt material to a tared aluminum pan and dry it at 120° C. for 2 hours and weigh to determine the mass of undissolved cured hot-melt material. Gel %=100% x (mass undissolved cured hot-melt material)/(starting sample mass).

If the UV cured sample has greater than 50 gel % then it is considered suitably curable.

### Optical Transmittance

Determine % T for cured compositions using 200 micrometer thick films of cured composition and Haze-Guard Plus (BYK Gardner) using ASTM D1003.

TABLE 5

| Component | Ex 1 | Ex 2 | Ex 3 | Ex 4 | Ex 5 | CE A | CE B | CE C | CE D | CE E |
|---|---|---|---|---|---|---|---|---|---|---|
| Comment | | | | | | No | No | Mono | Non | Higher |
| | | | | | | Acrylate | alkenyl | acrylate | RL | wt % |
| | | | | | | | on RL | cross- | | acrylates |
| | | | | | | | | linker | | |
| Component | Mass-parts | | | | | | | | | |
| RL 1* | 96.1 | | | | | | | | | |
| RL 2* | | | | 97.9 | | | | | | |
| RL 3* | | 96.4 | 93.8 | | | 99.5 | | 91.1 | | |
| RL 4* | | | | | | | | | | 69.7 |
| RL 5* | | | | | 79.6 | | | | | |
| RL 6* | | | | | | | 96.0 | | | |
| MP148SP | | | | | | | | | 90.5 | |
| Crosslinker 1 | 3.4 | | | 2.0 | 19.9 | | 3.5 | | 9.0 | 29.8 |
| Crosslinker 2 | | 3.1 | | | | | | | | |
| Crosslinker 3 | | | 5.7 | | | | | | | |
| Crosslinker 4 | | | | | | | | 8.4 | | |
| Photo Initiator | 0.5 | 0.5 | 0.5 | 0.1 | 0.5 | 0.5 | 0.5 | 0.5 | 0.5 | 0.5 |

Characterization

| | | | | | | | | | | |
|---|---|---|---|---|---|---|---|---|---|---|
| [Ac]/[Vi] | 2.0 | 2.0 | 2.0 | 1.0 | 14.1 | No Ac | No Vi | 2.0 | 13.1 | 24.0 |
| Softening Point | | | | | | | | | | |
| (° C.) | | | | | | | | | | |
| Ratio of viscosity | 1437 | 3833 | 780 | 111 | 124 | 764 | 2244 | 1345 | 9.5 | 26 |
| at 25° C. to | | | | | | | | | | |
| viscosity at 100° C. | | | | | | | | | | |
| Storage Modulus | 2.3 | 6.9 | 5.1 | 0.8 | 0.012 | 8.1 | 6.8 | 0.34 | 7 × 10⁻⁷ | 0.003 |
| @ 25° C. (MPa) | | | | | | | | | | |
| Tan δ (25° C.) | 0.64 | 0.31 | 0.30 | 0.27 | 1.3 | 0.12 | 0.27 | 0.71 | 100 | 1.1 |
| Gel % | 70.3 | 62.8 | 58.2 | 71.4 | 73.5 | 0 | 0 | 0 | 44.4 | 84.3 |
| % T | 95.1 | 95.3 | 95.5 | 04.9 | 94.8 | 95.4 | 95.5 | 95.5 | NA* | 93.8 |

*Sample did not cure to a solid film so % T was not able to be determined.

The invention claimed is:

1. A hot-melt composition comprising:
(a) 80 to 99 mass-parts of at least one a T^{Ar}-D based resin-linear block copolymer comprising T^{Ar}-type siloxane unit blocks and D-type siloxane unit blocks, where:
(i) T^{Ar}-type siloxane blocks are joined to D-type siloxane unit blocks with linkages selected from those having structure (I): 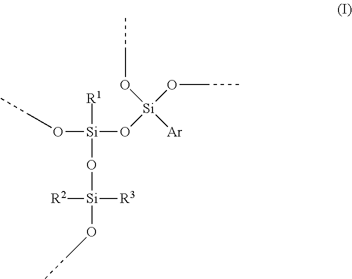
wherein Ar is C₆-C₂₀ aryl; R¹ is selected from C₁-C₂₀ alkyl and C₂-C₂₀ alkenyl groups provided that that the average concentration of alkenyl R¹ groups for the a T^{Ar}-D based resin-linear block copolymer is in a range of 0.5 to 3.0 mole-percent relative to total moles of silicon atoms; and R², and R³ independently are C₁-C₂₀ hydrocarbyl, each dashed line corresponds to a valence bond to a silicon, hydrogen or hydrocarbyl group;
and wherein:
(ii) the mole ratio of T^{Ar}-type siloxane unit blocks to D-type siloxane unit blocks is at least 2;
(iii) the resin-linear block copolymer contains 8 to 35 mole-percent Si—OR′ bonds relative to moles of silicone atoms where R′ is H or an a C₁-C₈ hydrocarbyl;
(iv) each D-type siloxane unit block contains on average 20 to 200 D-type siloxane units; and
(v) each T^{Ar}-type siloxane unit block has a weight-average molecular weight in a range of 500 to 10,000 grams per mole;
(b) 0.5 to 20 mass-parts of a crosslinker containing an average of at least two (meth)acryloxy groups per molecule;
(c) 0.1 to 10 mass-parts of radical photo-initiator;
(d) zero to 2.0 mass-parts of an ultraviolet stabilizer; and
(e) zero to 2.0 mass-parts of an adhesion promoter.

2. The hot-melt composition of claim 1, wherein the resin-linear block copolymer is free of (meth)acryloxy groups.

3. The hot-melt composition of claim 1, wherein Ar is phenyl, R¹ is vinyl and R² and R³, are independently selected from methyl and ethyl groups.

4. The hot-melt composition of claim 1, wherein the composition is free of unbound Q-based resin particles.

5. The hot-melt composition of claim 1, wherein the crosslinker is one or more than one compound selected from compounds having the average chemical structure (III) and (IV): 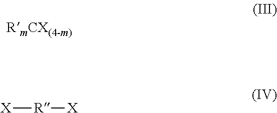
where each R′ is independently in each occurrence selected from alkyl groups having from one to 20 carbon atoms, each X is independently selected from —OC(O)CH═CH₂ and —OC(O)C(CH₃)═CH₂ groups, and R″ is an alkylene group having from one to 20 carbon atoms.

6. A process comprising the steps of heating the hot-melt composition of claim 1 to soften the hot-melt composition and then coating the softened hot-melt composition over at least a portion of a substrate to form a coating of the hot-melt composition over at least a portion of a surface of the substrate.

7. The process of claim 7, wherein the process further comprising exposing the coating of the hot-melt composition to ultraviolet light to cause crosslinking of the composition coating.

8. An article comprising the hot-melt composition of claim 1 coating at least a portion of a surface of a substrate.

9. The article of claim 8, wherein the substrate comprises light emitting diodes.
